(19) United States
(12) Patent Application Publication
(10) Pub. No.: US 2010/0132996 A1
(43) Pub. Date: Jun. 3, 2010

(54) ELECTROMAGNETIC BANDGAP STRUCTURE AND PRINTED CIRCUIT BOARD

(75) Inventors: Mi-Ja Han, Suwon-si (KR); Han Kim, Yongin-si (KR); Dae-Hyun Park, Jung-gu (KR); Kang-Wook Bong, Seoul (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD

(21) Appl. No.: 12/466,677

(22) Filed: May 15, 2009

(30) Foreign Application Priority Data
Nov. 28, 2008 (KR) 10-2008-0119913

(51) Int. Cl. H05K 1/11

(52) U.S. Cl. 174/262

(57) ABSTRACT

In accordance with an embodiment of the present invention, an electromagnetic bandgap structure includes a plurality of conductive plates, and a multi-via connection part, which electrically connects any two of the plurality of conductive plates with each other. Here, the multi-via connection part includes: a first multi-via, including a first via, having one end part connected to one of the two conductive plates, and at least one other via connected in serial to the first via through a conductive trace; a second multi-via, including a second via, having one end part connected to the other of the two conductive plates, and at least one other via connected in serial to the second via through a conductive trace; and a conductive connection pattern, connecting any one of the vias included in the first multi-via and any one of the vias included in the second multi-via with each other.

### CROSS-REFERENCE TO RELATED APPLICATIONS

This application claims the benefit of Korean Patent Application No. 10-2008-0119913, filed with the Korean Intellectual Property Office on Nov. 28, 2008, the disclosure of which is incorporated herein by reference in its entirety.

### BACKGROUND

1. Technical Field

The present invention relates to an electromagnetic bandgap structure, more specifically to an electromagnetic bandgap structure and a printed circuit board having the same that prevent a signal ranging a predetermined frequency band from being transmitted.

2. Description of the Related Art

New electronic apparatuses and communication apparatuses are increasingly becoming smaller, thinner and lighter, reflecting today's emphasis on growing mobility.

These electronic and communication apparatuses have various complex electronic circuits (i.e. analog circuits and digital circuits) for performing their functions and operations. These electronic circuits typically carry out their functions by being implemented in a printed circuit board (PCB). The electronic circuits on the PCB commonly have different operation frequencies from one another.

The printed circuit board in which various electronic circuit boards are implemented often has a noise problem, caused by the transfer of an electromagnetic (EM) wave resulted from the operation frequency and its corresponding harmonics components of one electronic circuit to another electronic circuit. The transferred noise can be roughly classified into radiation noise and conduction noise.

The radiation noise can be easily prevented by covering a protective cap on the electronic circuit. However, preventing the conduction noise (refer to the reference numeral 150 of FIG. 1) is not as easy, because the conduction noise is transferred through a signal transfer path inside the board.

The noise problem will be described in more detail with reference to FIG. 1. FIG. 1 is a sectional view showing a printed circuit board including two electronic circuits having different operation frequencies. Although FIG. 1 shows a 4-layered printed circuit board 100, it shall be evident that the printed circuit board can be modified to have a 2, 6 or 8-layered structure.

As shown in FIG. 1, the printed circuit board 100 includes four metal layers 110-1, 110-2, 110-3 and 110-4 (hereinafter, collectively referred to as 110) and dielectric layers 120-1, 120-2 and 120-3 (hereinafter, collectively referred to as 120) interposed between metal layers 110. The top metal layer 110-1 of the printed circuit board 100 is implemented with two electronic circuits 130 and 140 having different operation frequencies (hereinafter, referred to as a first electronic circuit 130 and a second electronic circuit 140, respectively). Here, it is assumed that the two electronic circuits 130 and 140 are digital circuits.

Here, if it is assumed that the metal layer represented by the reference numeral 110-2 is a ground layer and the metal layer represented by the reference numeral 110-3 is a power layer, each ground pin of the first electronic circuit 130 and the second electronic circuit 140 is electrically connected to the metal layer represented by the reference numeral 110-2 and each power pin is electrically connected to the metal layer represented by the reference numeral 110-3. In the printed circuit board 100, every ground layer is also electrically connected to each other through vias. Similarly, every power layer is also electrically connected to each other through vias. As an example, a via 160 electrically connects the metal layers of the reference numerals 110-1, 110-3, and 110-4 as shown in FIG. 1.

At this time, if the first electronic circuit 130 and the second electronic circuit 140 have different operation frequencies, a conductive noise 150 caused by an operation frequency of the first electronic circuit 130 and its harmonics components is transferred to the second electronic circuit 140. This has a disadvantageous effect on the accurate function/operation of the second electronic circuit 140.

With the growing complexity of electronic apparatuses and higher operation frequencies of digital circuits, it is increasingly difficult to solve this conduction noise problem. Especially, the typical bypass capacitor method or decoupling capacitor method for solving the conductive noise problem is no longer adequate, as the electronic apparatuses use a higher frequency band.

Moreover, the aforementioned solutions are not adequate when several active devices and passive devices need to be implemented in a complex wiring board having various types of electronic circuits formed on the same board or in a narrow area such as a system in package (SiP) or when a high frequency band is required for the operation frequency, as in a network board.

Accordingly, an electromagnetic bandgap structure (EBG) is recently receiving attention as a scheme to solve the aforementioned conductive noise. This is for the purpose of blocking a signal ranging a certain frequency band by arranging the EBG having a certain structure in a printed circuit board, and the typical EBG has roughly two, namely a Mushroom type EBG(MT-EBG) and a Planar type EBG(PT-EBG).

A general form of the MT-EBG is illustrated in FIG. 2.

For example, the MT-EBG has the structure in which a plurality of EBG cells (refer to the reference numeral 230 of FIG. 2) having a mushroom form are interposed between two metal layers which function as a power layer and a ground layer. FIG. 2 shows only four EBG cells for the convenience of illustration.

With reference to FIG. 2, the MT-EBG 200 further forms a metal plate 231 between a first metal layer 210 and a second metal layer 220 that function as each one of the ground layer and the power layer, and has a form in which the mushroom type structures 230 connecting the first metal layer 210 and the metal plate 231 through a via 232 are repeatedly arranged. At this time, a first dielectric layer 215 is interposed between the first metal layer 210 and the metal plate 231, and a second dielectric layer 225 is interposed between the metal plate 231 and the second metal layer 220.

Such MT-EBG 200 performs the function as a sort of band stop filter by having the state of which a capacitance component formed by the second metal layer 220, the second dielectric layer 225 and the metal plate 231, and an inductance component formed by the via 232 penetrating the first dielectric layer 215 and connecting the first metal layer 210 and the metal plate 231, are connected in L-C series between the first metal layer 210 and the second layer 220.

However, the largest demerit of this structure is the increase of layers, because it needs at least 3 layers to implement the MT-EBG 200. In this case, not only the manufacturing cost of the PCB increases, but also the design freedom is limited.

On the one hand, PT-EBG is illustrated in FIG. 3.

PT-EBG has a structure in which a plurality of EBG cells (refer to the reference numeral 320-1 of FIG. 3) having a certain pattern are repeatedly arranged through any entire metal layer that functions as each one of the ground layer and the power layer. FIG. 3 also shows only four EBG cells for the convenience of illustration.

With reference to FIG. 3, PT-EBG 300 has a form in which any metal layer 310 and a plurality of metal plates 321-1, 321-2, 321-3 and 321-4, which are placed on another planar surface, are bridged to each other through a certain part of metal plates (the edge end of each metal plate in FIG. 3) by metal branches 322-1, 322-2, 322-3 and 322-4.

At this time, the metal plates 321-1, 321-2, 321-3, and 321-4 having a large size constitute the low impedance area and the metal branches having a small size constitute the high impedance area. Accordingly, PT-EBG performs the function as a band stop filter that can block a noise ranging a certain frequency band through the structure in which the low impedance area and the high impedance area are repeatedly formed in turn.

Although such PT-EBG structure has a merit that is enough to constitute the bandgap structure by using only two layers in contrast to the structure of MT-EBG, there is not only a difficulty in making cells smaller but also a design limit, which makes it hard to apply to various application products because it is formed in a lager area. This is because PT-EBG forms the EBG structure by not utilizing various parameters but using only two impedance components.

As described above, the EBG structures according to the conventional technology, such as the MT-EBG and the PT-EBG, have a limit in adjusting each bandgap frequency band appropriate to the conditions and features that are required for various application products or lower a conductive noise below the intended noise level within a pertinent bandgap frequency band.

Accordingly, the research for the EBG structure being extensively applied to various application products for which the required bandgap frequency bands separately differ, not to mention solving the aforementioned conductive noise problem, is urgently needed.

### SUMMARY

Accordingly, the present invention provides an electromagnetic bandgap structure and a printed circuit board having the same that can block a conductive noise of a certain frequency band.

The present invention also provides a printed circuit board that can solve a conductive noise problem through an electromagnetic bandgap structure having a certain structure in the printed circuit board without using a bypass capacitor or a decoupling capacitor.

In addition, the present invention provides an electromagnetic bandgap structure and a printed circuit board having the design flexibility and design freedom appropriate for the printed circuit board and being extensively applied to various application products (for example, an electronic apparatus (e.g. a mobile communication terminal) including an RF circuit and a digital circuit which are placed in the same board, SiP (System in Package), and network board, etc.) by the realization of various bandgap frequency band.

Other problems that the present invention solves will become more apparent through the following description.

An aspect of the present invention provides an electromagnetic bandgap structure that can block a noise of a certain frequency band.

In accordance with an embodiment of the present invention, an electromagnetic bandgap structure includes a plurality of conductive plates, and a multi-via connection part, which electrically connects any two of the plurality of conductive plates with each other. Here, the multi-via connection part includes: a first multi-via, including a first via, having one end part connected to one of the two conductive plates, and at least one other via connected in serial to the first via through a conductive trace; a second multi-via, including a second via, having one end part connected to the other of the two conductive plates, and at least one other via connected in serial to the second via through a conductive trace; and a conductive connection pattern, connecting any one of the vias included in the first multi-via and any one of the vias included in the second multi-via with each other.

In an embodiment of the present invention, the plurality of conductive plates can be placed on a same planar surface.

In an embodiment of the present invention, a dielectric layer can be placed above or below the plurality of conductive plates, and the vias included in the first multi-via and the second multi-via can be formed to penetrate through the dielectric layer.

In an embodiment of the present invention, if the electromagnetic bandgap structure further includes a conductive layer between the plurality of conductive plates and the dielectric layer, a clearance hole can be formed in a part of the conductive layer coinciding with a path through which the multi-via connection part will pass such that the multi-via connection part and the conductive layer are electrically separated from each other.

In an embodiment of the present invention, a clearance hole can be formed in a part coinciding with a path through which the multi-via connection part passes, except for parts of the conductive plates to be connected to the one end part of the first via and the one end part of the second via.

In an embodiment of the present invention, the conductive trace and the conductive connection pattern can be manufactured as a straight-line form or a fine form broken one or more times.

Another aspect of the present invention provides a printed circuit board including an electromagnetic bandgap structure. The electromagnetic bandgap structure includes a plurality of conductive plates and a multi-via connection part electrically connecting any two of the plurality of conductive plates and disposed at an area of a noise transferable path between a noise source point and a noise blocking destination point of the printed circuit board.

Here, the multi-via connection part includes: a first multi-via, including a first via, having one end part connected to one of the two conductive plates, and at least one other via connected in serial to the first via through a conductive trace; a second multi-via, including a second via, having one end part connected to the other of the two conductive plates, and at least one other via connected in serial to the second via through a conductive trace; and a conductive connection pattern, connecting any one of the vias included in the first multi-via and any one of the vias included in the second multi-via with each other.

In an embodiment of the present invention, the plurality of conductive plates can be placed on a same planar surface.

In an embodiment of the present invention, a dielectric layer can be placed above or below the plurality of conductive plates, and the vias included in the first multi-via and the second multi-via can be formed to penetrate through the dielectric layer.

In an embodiment of the present invention, if the printed circuit board further includes a conductive layer between the plurality of conductive plates and the dielectric layer, a clearance hole can be formed in a part of the conductive layer coinciding with a path through which the multi-via connection part will pass such that the multi-via connection part and the conductive layer are electrically separated from each other.

In an embodiment of the present invention, the conductive plates can be electrically connected to one of a ground layer and a power layer, and the conductive layer can be electrically connected to the other of the ground layer and the power layer.

In an embodiment of the present invention, the conductive plates can be electrically connected to one of a ground layer and a signal layer, and the conductive layer can be electrically connected to the other of the ground layer and the signal layer.

In an embodiment of the present invention, a clearance hole can be formed in a part coinciding with a path through which the multi-via connection part passes, except for parts of the conductive plates to be connected to the one end part of the first via and the one end part of the second via.

In an embodiment of the present invention, the conductive trace and the conductive connection pattern can be manufactured as a straight-line form or a line form broken one or more times.

In an embodiment of the present invention, if two electronic circuits having different operation frequencies are installed in the printed circuit board, the noise source point and the noise blocking destination point can correspond to one position and another position, respectively, in which the two electric circuits are to be installed.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a cross-sectional view showing a printed circuit board including two electronic circuits having different operation frequencies.

FIG. 2 is a schematic view showing an MT-EBG structure as an electromagnetic bandgap structure in accordance with a conventional art.

FIG. 3 is a schematic view showing a PT-EBG structure as another example of an electromagnetic bandgap structure in accordance with a conventional art.

FIG. 4A is a 3-D perspective view showing an electromagnetic bandgap structure including a stitching via and having a block principle similar to the present invention.

FIG. 4B is a schematic view showing an equivalent circuit of the electromagnetic bandgap structure shown in FIG. 4A.

FIG. 4C is a 3-D perspective view showing a transformational example of the electromagnetic bandgap structure shown in FIG. 4A.

FIG. 5A is a plan view showing a configuration of an electromagnetic bandgap structure including a stitching via having a rectangular metal plate.

FIG. 5B is a plan view showing a configuration of an electromagnetic bandgap structure including a stitching via having a triangular metal plate.

FIG. 5C and FIG. 5D are plan views showing a configuration of an electromagnetic bandgap structure including a stitching via consisting of a plurality of groups having different sized metal plates.

FIG. 5E is a plan view showing a band-shaped configuration of an electromagnetic bandgap structure including a stitching via.

FIG. 6 is a 3-D perspective view showing an electromagnetic bandgap structure including a multi-via connection part in accordance with an embodiment of the present invention.

FIG. 7 is a detailed view of the multi-via connection part shown in FIG. 6.

FIG. 8A through FIG. 8C show graphs showing a bandgap frequency property of the electromagnetic bandgap structure shown in FIG. 6.

### DETAILED DESCRIPTION

Since there can be a variety of permutations and embodiments of the present invention, certain embodiments will be illustrated and described with reference to the accompanying drawings. This, however, is by no means to restrict the present invention to certain embodiments, and shall be construed as including all permutations, equivalents and substitutes covered by the spirit and scope of the present invention.

Throughout the description of the present invention, when describing a certain technology is determined to evade the point of the present invention, the pertinent detailed description will be omitted. Terms such as “first” and “second” are used only to distinguish one element from the other.

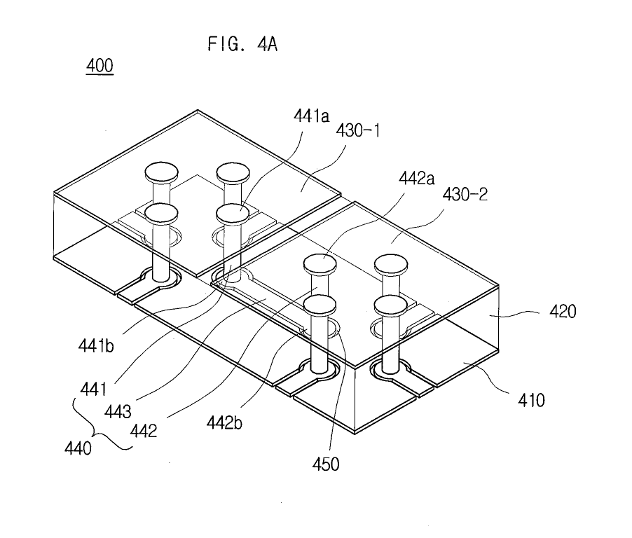

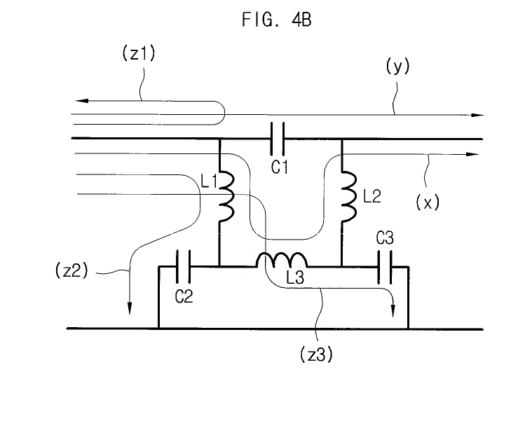

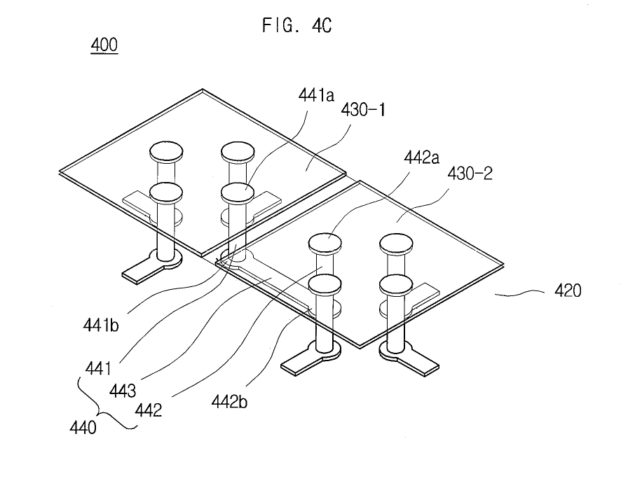

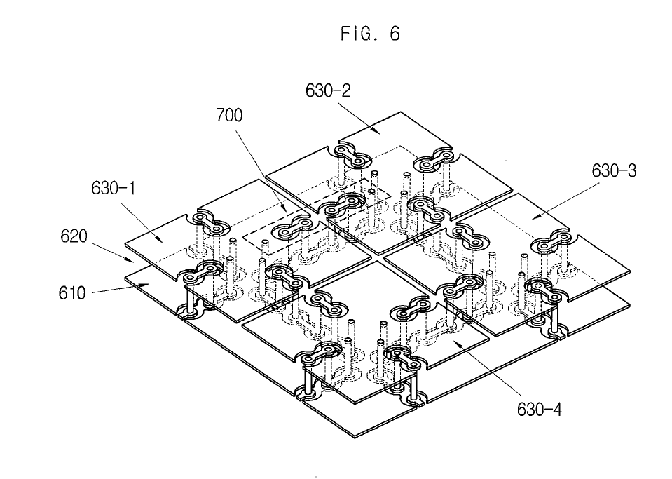

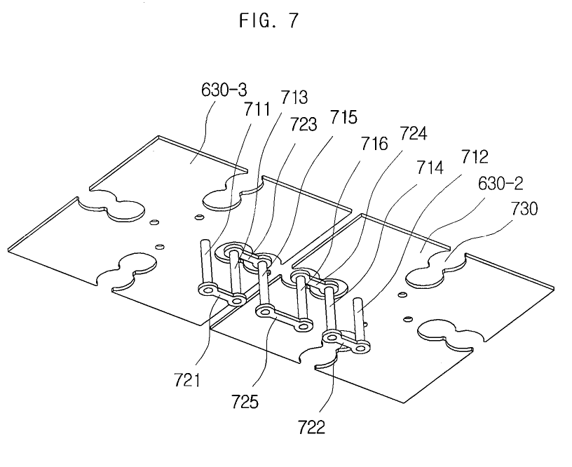

Hereinafter, some examples of an electromagnetic bandgap structure including a stitching via having a basic principle similar to a blocking noise principle in accordance with some embodiments of the present invention will be described with reference to FIG. 4A through FIG. 4C for easy understanding of the present invention before an electromagnetic bandgap structure and a printed circuit board having the same are described with reference to FIG. 6 and FIG. 7.

Although a metal layer, a metal plate and a metal trace are used throughout the description of an electromagnetic bandgap structure of the present invention, it shall be evidently understood by any person of ordinary skill in the art that any other conductive layers, plates and traces can be substituted for the metal layer, the metal plate and the metal trace.

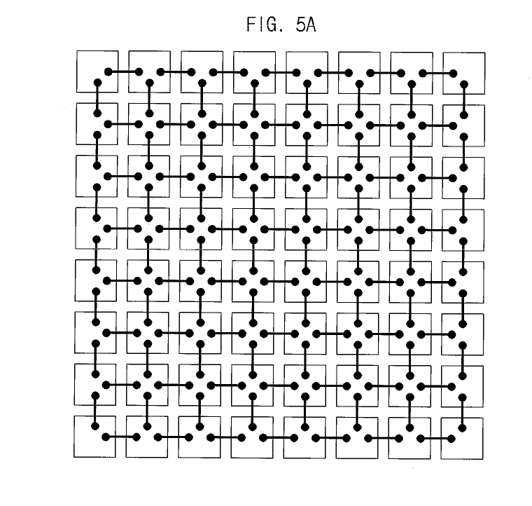

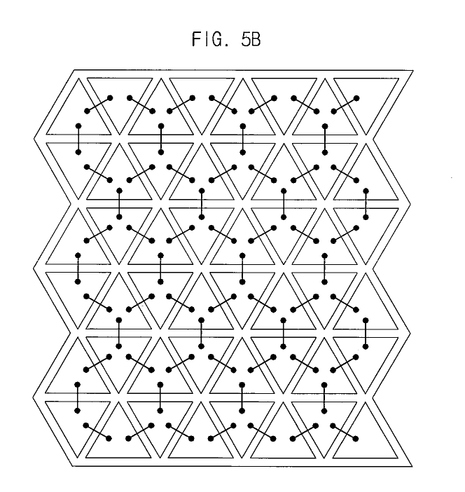

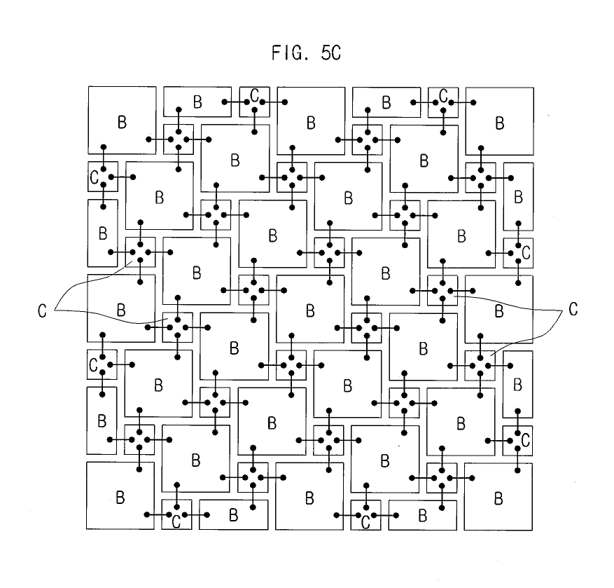

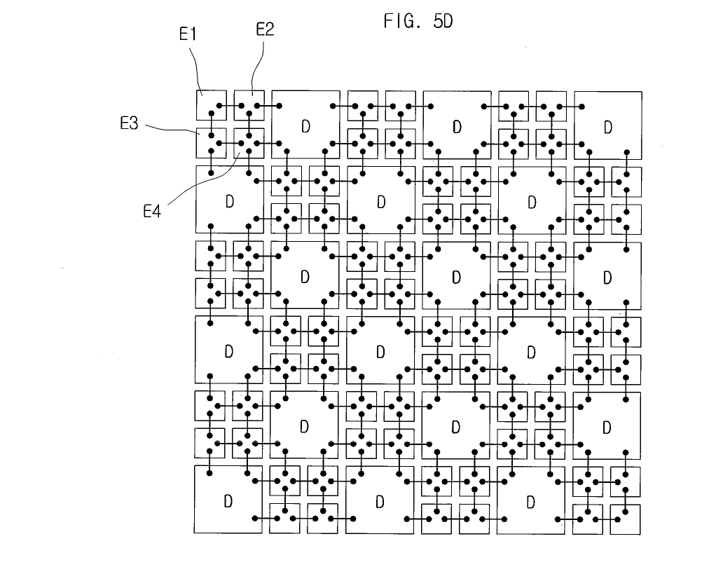

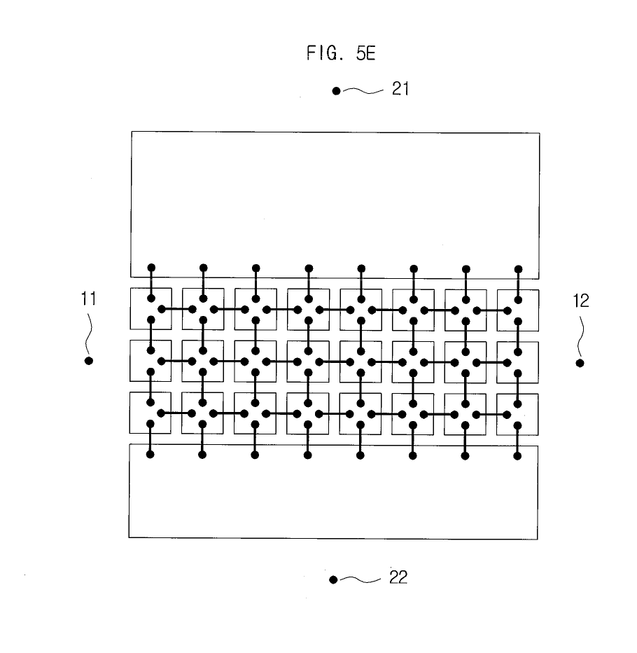

Also, even though FIG. 4A, FIG. 4C, FIG. 6 and FIG. 7 show only two or four metal plates for the convenience of illustration, the electromagnetic bandgap structure can have a plurality of metal plates repeatedly arranged as its elements as shown in FIG. 5A through FIG. 5E (the same can be applied to FIG. 6 through FIG. 9).

An electromagnetic bandgap structure 400 shown in FIG. 4A can include a metal layer 410, a plurality of metal plates 430-1 and 430-2 (hereinafter, referred to as a first metal plate 430-1 and a second metal plate 430-2) spaced from the metal layer 410 and a stitching via 440. The electromagnetic bandgap structure 400 of FIG. 4A can have 2-layered planar structure including a first layer that can consist of the metal layer 410 and a second layer that can consist of the plurality of metal plates 430-1 and 430-2. A dielectric layer 420 can be interposed between the metal layer 410 and the plurality of metal plates 430-1 and 430-2.

Here, FIG. 4A shows only elements constituting the electromagnetic bandgap structure (i.e. the only part constituting the 2-layered electromagnetic bandgap including the stitching via) for the convenience of illustration. Accordingly, the metal layer 410, and the plurality of metal plates 430-1 and 430-2 shown in FIG. 4A may be any two layers of a multi-layered printed circuit board. In other words, it shall be evident that there can be at least one additional metal layer below the metal layer 410, above the metal plates 430-1 and 430-2 and/or between the metal layer 410 and the metal plates 430-1 and 430-2. Similarly, this can be applied to the present invention shown in FIG. 6.

In addition, the electromagnetic bandgap structure 400 shown in FIG. 4A (the same can be applied to the present invention shown in FIG. 6) can be placed between any two metal layers separately constituting the power layer and the ground layer in order to block a conductive noise. Since the conductive noise problem is not limited to the space between the power layer and the ground layer, the electromagnetic bandgap structure shown in FIG. 4A can be placed between any two ground layers or power layers placed on different layers from each other in a multi-layered printed circuit board.

Accordingly, the metal layer 410 may be any one metal layer for transferring an electric signal in a printed circuit board. The metal layer 410, for example, can be any metal layer functioning as the power layer or the ground layer, or any metal layer functioning as a signal layer constituting a signal line.

The metal layer 410 can be placed on a planar surface different from the planar surface in which the plurality of metal plates are placed and electrically separated from the plurality of metal plates. In other words, the metal layer 410 can form a layer that is different from the plurality of metal plates 430-1 and 430-2 with regard to electrical signals in the printed circuit board. For example, if the metal layer 410 is the power layer, the metal plates can be electrically connected to the ground layer. If the metal layer 410 is the ground layer, the metal plates can be electrically connected to the power layer. Alternatively, if the metal layer 410 is the signal layer, the metal plates can be electrically connected to the ground layer. If the metal layer 410 is the ground layer, the metal plates can be electrically connected to the signal layer. Similarly, this can be applied to FIG. 6.

The plurality of metal plates 430-1 and 430-2 can be placed on a planar surface above the metal layer 410. Any two metal plates can be electrically connected to each other through a stitching via. As such, each stitching via electrically connecting any two metal plates to each other can electrically connect every metal plate as one circuit.

Here, FIG. 4A shows the form (i.e. the form of FIG. 5A) that a metal plate and its adjacent metal plates can be electrically connected to each other through one stitching via each, and as a result, every metal plate can be electrically connected to each other. However, as long all metal plates can be formed as a closed loop by being electrically connected to each other, it can be possible to use any method of connecting the metal plates to each other through the stitching via.

Also, even though FIG. 4A shows each of metal plates having a square shape of the same size for the convenience of illustration, various other modifications can be possible (the same can be applied to FIG. 6). This will be briefly described with reference to FIG. 5A through FIG. 5E.

For example, the metal plates can have various polygonal shapes including not only a rectangle as shown in FIG. 5A, and a triangle as shown in FIG. 5B, but also a hexagon, an octagon, etc. Of course, the metal plate may not be limited to a certain shape such as a circle or an ellipse. Each of the metal plates can also have the same size (e.g. area and thickness) as shown in FIG. 5A, FIG. 5B and FIG. 5E. If the metal plates have different sizes, the metal plates can be distinguished and placed according to each of a plurality of groups having different sizes as shown in FIG. 5C or FIG. 5D.

In the case of FIG. 5C, metal plates B having a relatively bigger size and metal plates C having a relatively smaller size can be alternately arranged. In the case of FIG. 5D, metal plates D having a relatively bigger size and metal plates E1, E2, E3 and E4 having a relatively smaller size can be arranged. The small metal plates E1, E2, E3 and E4 can be grouped in a 2×2 form, and can occupy the area similar to the large metal plate D.

In addition, while the cells of the electromagnetic bandgap structures can be densely arranged on the whole part of an inner surface of the printed circuit board as shown in FIG. 5A through 5D, the cells can be naturally arranged on some paths as shown in FIG. 5E. For example, as shown in FIG. 5E, if it is assumed that a point 11 refers to a noise source point and a point 12 refers to a noise blocking destination point, the cells can be repeatedly arranged in at least one line along a noise transferable path between the noise source point 11 and the noise blocking destination point 12. Alternatively, as shown in FIG. 5E, if it is assumed that a point 21 refers to the noise source point and a point 22 refers to the noise blocking destination point, the cells can be arranged in at least one line to have the shape crossing and blocking a noise transferable path between the noise source point 21 and the noise blocking destination point 22 (i.e. the shape of being shielded by a blocking shield).

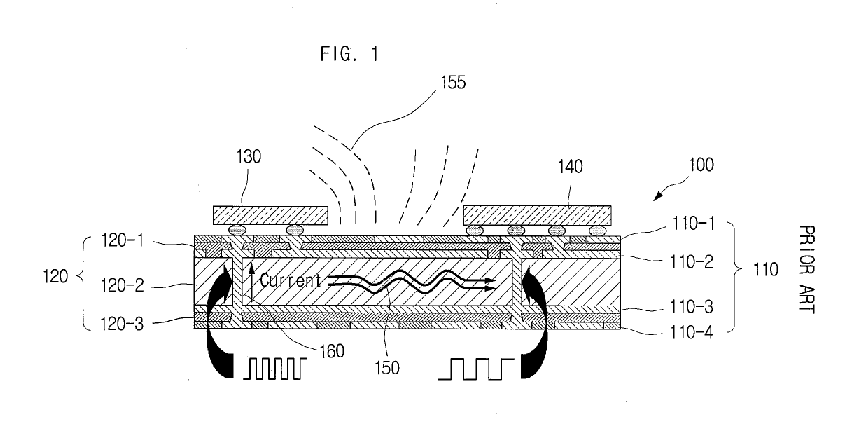

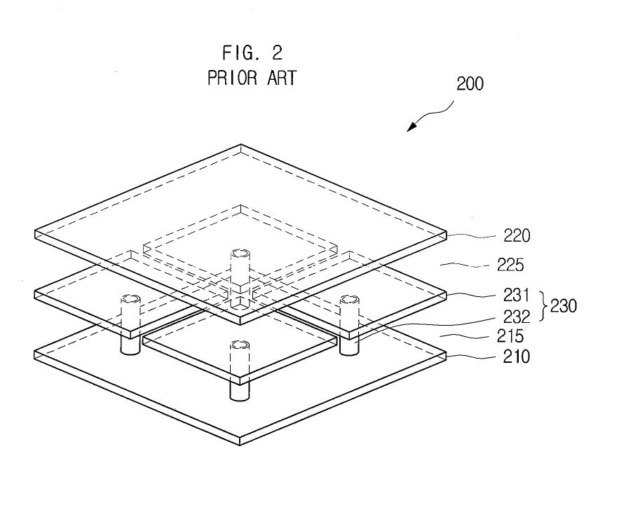

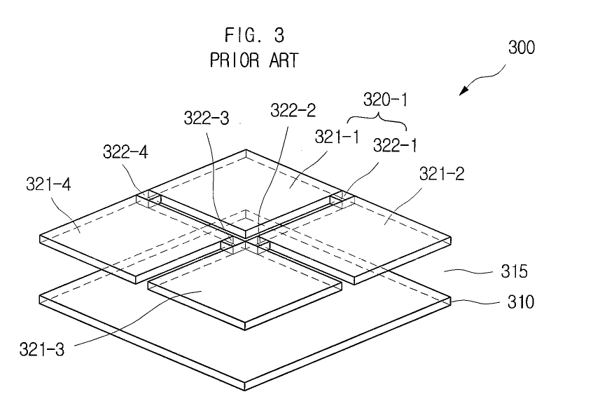

Here, if it is assumed that any two electric circuits having different operation frequencies (refer to the first electric circuit 130 and the second electric circuit 140 in FIG. 1, described above) are implemented in the printed circuit board, the noise resource point and the noise blocking destination point can correspond to each position in which the two electric circuits will be implemented.

A stitching via can electrically connect any two metal plates of a plurality of metal plates to each other. All accompanying drawings of this specification show that the stitching via electrically connects two adjacent metal plates to each other. However, it may be unnecessary that any two metal plates connected by the stitching via are adjacent to each other. Also, even though it is shown that one metal plate is connected to another metal plate by one stitching via, it is evidently unnecessary that the electromagnetic bandgap structure has any limitation to the number of the stitching vias connecting any two metal plates. However, all below descriptions focus on the case that two adjacent metal plates are connected to each other by one stitching via.

The stitching via 440 can be formed to include a first via 441, a second via 442 and a connection pattern 443 in order to electrically connect two adjacent metal plates.

Herein, the first via 441 can be formed to start from one end part 441a connected to the first metal plate 430-1 and penetrate the dielectric layer 420, and the second via 442 can be formed to start from one end part 442a connected to the second metal plate 430-2 and penetrate the dielectric layer 420. The connection pattern 443 can be placed on the same planar surface as the metal layer 410 and have one end part, connected to the other end part 441b of the first via 441, and the other end part, connected to the other end part 442b of the second via 442. At this time, it is evident that a via land having a larger size than the via can be formed at one end part and the other end part of each via in order to reduce a position error of a drilling process for forming the via. Accordingly, the pertinent detailed description will be omitted.

At this time, a clearance hole 450 can be formed at an edge of the connection pattern 443 of the stitching via 440 in order to prevent the metal plates 430-1 and 430-2 to be electrically connected to the metal layer 410.

The two adjacent metals 430-1 and 430-2 may not be connected on the same planar surface in the electromagnetic bandgap structure of FIG. 4A. Instead, the two adjacent metals 430-1 and 430-2 can be connected to each other through another planar surface (i.e. the same planar surface as the metal layer 410) by the stitching via 440. Accordingly, the electromagnetic bandgap structure 400 having the stitching via 440 of FIG. 4A can more easily acquire an inductance component with a longer length than that of connecting the adjacent metal plates to each other on the same planar surface under the same conditions. In addition, since the adjacent metal plates of the present invention are connected to each other by the stitching via 440, it is unnecessary to form an additional pattern for electrically connecting the metal plates placed on a second layer. This can make a spaced distance between the metal plates narrower. Accordingly, it can be possible to increase the capacitance component formed between the adjacent metal plates.

Described below is the principle by which the structure shown in FIG. 4A can function as the electromagnetic bandgap structure blocking a signal of a certain frequency band. The dielectric layer 420 can be interposed between the metal layer 410 and the metal plates 430-1 and 430-2. This may cause a capacitance component to be formed between the metal layer 410 and the metal plates 430-1 and 430-2 and between the two adjacent metal plates. Also, there may be an inductance component connecting through the first via 441→the connection pattern 443→the second via 442 between the two adjacent metal plates by the stitching via 440. At this time, the value of the capacitance component can vary according to various factors such as the spaced distances between the metal layer 410 and the metal plates 430-1 and 430-2 and between the two adjacent metal plates, the dielectric constant of a dielectric material forming the dielectric layer 420 and the size, shape and area of the metal plate. Also, the value of the inductance component can vary according to various factors such as the shape, length, depth, width and area of the first via 441, a second via 442 and the connection pattern 443. Accordingly, adjusting and designing various aforementioned factors adequately can make it possible to allow the structure of FIG. 4A to function as the electromagnetic bandgap structure (i.e. a band stop filter) for removing or blocking a certain noise or a certain signal of an object frequency band. This can be easily understood through the equivalent circuit of FIG. 4B.

Comparing the equivalent circuit of FIG. 4B with the electromagnetic bandgap structure of FIG. 4A, an inductance component L1 can correspond to the first via 441, and an inductance component L2 can correspond to the second via 442. An inductance component L3 can correspond to the connection pattern 443. C1 can be a capacitance component by the metal plates 430-1 and 430-2 and another dielectric layer and another metal layer to be placed above the metal plates 430-1 and 430-2. C2 and C3 can be capacitance components by the metal layer 410 placed on the same planar surface as the connection pattern 443 and another dielectric layer and another metal layer to be placed below the planar surface of the connection pattern 443.

The electromagnetic bandgap structure shown in FIG. 4A can function as a band stop filter, which blocks a signal of a certain frequency band according to the above equivalent circuit. In other words, as seen in the equivalent circuit of FIG. 4B, a signal x of a low frequency band (refer to FIG. 4B) and a signal y of a high frequency band (refer to FIG. 4B) can pass through the electromagnetic bandgap structure, and signals z1, z2 and z3 of a certain frequency band (refer to FIG. 4B) ranging between the low frequency band and the high frequency band are blocked by the electromagnetic bandgap structure.

Accordingly, if the structure of FIG. 4A is repeatedly arranged on a whole part (refer to FIG. 5A. FIG. 5B, FIG. 5C and FIG. 5D) or a part (refer to FIG. 5E) of an inner surface of the printed circuit board (the same can be applied to the structure of FIG. 6 in accordance with an embodiment of the present invention described below) as a noise transferable path, it is possible to function as the electromagnetic bandgap structure that can prevent a signal of a certain frequency band from being transferred.

The identical or similar idea can be applied to the electromagnetic bandgap structure of FIG. 4C.

The electromagnetic bandgap structure of FIG. 4C has no metal layer corresponding to the reference numeral 410 as compared with the electromagnetic bandgap structure of FIG. 4A.

If there is a metal layer on the same planar surface to correspond to an area on which the connection pattern 443 will be formed, the connection pattern 443 can be manufactured in the form of being accommodated in the clearance hale 450 formed in the metal layer 410 on the same planar surface as shown in FIG. 4A. However, no additional metal layer may be placed in the area in which the connection pattern 443 will be formed, as shown in FIG. 4C. Of course, there may be the dielectric layer 420 below the metal plates in FIG. 4C.

Although not shown in the accompanying drawings, it may not be always necessary that the 2-layered electromagnetic bandgap structure including the stitching via is formed to have a stacked structural form in which the metal plates 430-1 and 430-2 are stacked in the dielectric layer 420 and the dielectric layer 420 is stacked in the metal layer 410. The 2-layered electromagnetic bandgap structure including the stitching via can be formed to have another structural shape including a lower layer in which the metal plates are placed, an upper layer in which the metal layer is placed, the dielectric layer interposed between the lower layer and the upper layer and the stitching via, penetrating the dielectric layer (i.e. a structural form, with the position of the upper layer and the lower layer inversed from that of FIG. 4A).

Of course, this case can be expected to have the identical or similar noise blocking effect described above.

Hereinafter, the electromagnetic bandgap structure in accordance with an embodiment of the present invention will be described in detail with reference to FIG. 6 and FIG. 7. Below descriptions focus on the difference from the aforementioned electromagnetic bandgap structure, and the description of the content that can be duplicated or be equally applied as described above as shown in FIG. 4A through FIG. 5E (for example, the arrange method of the metal plates, the arrange position, the connection method, and the detail of the stitching via) will be omitted.

FIG. 6 is a 3-D perspective view showing an electromagnetic bandgap structure including a multi-via connection part in accordance with an embodiment of the present invention;

With reference to FIG. 6, an electromagnetic bandgap structure in accordance with an embodiment of the present invention includes a plurality of metal plates 630-1, 630-2, 630-3 and 630-4 and a multi-via connection part 700 electrically connecting any two of the plurality of metal plates. Of course, as described above, the plurality of metal plates 630-1, 630-2, 630-3 and 630-4 do not have to be placed on a same planar surface, unlike the example shown in the drawing.

The multi-via connection part 700 will be described in more detail hereafter with reference to FIG. 7, which focuses on only the multi-via connection part connecting the metal plates of the reference numerals 630-1 and 630-2.

In the present invention, the multi-via connection part includes a first multi-via, a second multi-via and a conductive connection pattern.

The first multi-via includes a via, having one end part connected to any one of the two metal plates, and at least one other via serially connected to the via through a conductive trace.

Corresponding to FIG. 7, the first multi-via consists of three vias 711, 713 and 715 including a via of the reference numeral 711 having one end part connected to the metal plate of the reference numeral 630-1, and two metal traces 721 and 713 connecting the vias.

Since a vialand is commonly formed in two end parts of the via to solve the error problem of the via processing, the parts connected to the metal trace can be the vialand formed in each end part of the via, but it will be omitted in below description for the convenience of description.

Like the first multi-via, the second multi-via includes a via, having one end part connected to the other of the two metal plates, and at least one other via serially connected to the via through a conductive trace.

Corresponding to FIG. 7, the second multi-via consists of three vias 712, 714 and 716 including a via of the reference numeral 712 having one end part connected to the metal plate of the reference numeral 630-2, and two metal traces 722 and 724 connecting the vias.

At this time, since the first multi-via and the second multi-via are electrically connected to each other through a conductive connection pattern (refer to the metal trace 725 of FIG. 7), the two metal plates 630-1 and 630-2 can be electrically connected to each other.

Hereafter, for the convenience of description, the metal plates of the reference numerals 630-1 and 630-2 are referred to as a first metal plate and a second metal plate, respectively, and the vias of the reference numerals 711 through 716 are referred to as a first through sixth via, respectively, and the metal traces of the reference numerals 721 through 725 are referred to as a first through fifth metal trace, respectively.

FIG. 6 and FIG. 7 illustrate that the first multi-via is serially connected as having the form of “S” between the first metal plate 630-1 and the metal layer 610 by the connection of three vias 711, 713 and 715 through two metal traces 721 and 723. However, two or serially connected vias are sufficient for the first multi-via. If the number of vias constituting the first multi-via is 2, the first multi-via will have the form of “C” between the first metal plate 630-1 and the metal layer 610 through one metal trace which will connect the vias. Of course, the first multi-via can have the structure in which 4 or more vias are serially connected through at least 3 metal traces, unlike the example shown in FIG. 6 and FIG. 7.

The aforementioned description of the first multi-via can be identically applied to the second multi-via.

In addition, FIG. 6 and FIG. 7 illustrate the structure in which the first via 711 of the first multi-via is directly connected to the first plate 630-1, and the third via 713 and the fifth via 715 are directly connected to the first via 711 to be electrically connected to the first metal plate 630-1. However, the via of the first multi-via directly connected to the metal plate 630-1 is unnecessary to be the first via 711 as shown in the drawing, but it can be the third via 713 or the fifth via 715. In other words, if the number of vias constituting the first multi-via is n (n being a natural number of greater than or equal to 2), it is sufficient as long as any one of the vias is directly connected to the metal plate 630-1 and another n-1 of the vias are connected to the via which is directly connected to the metal plate 630-1 regardless of the forming position of the vias.

Here, any one via of n-vias will be directly connected to the first metal plate 630-1 because another n-1 of the vias and the via which will be directly connected are necessary to have the structure of serial connection. If two or more vias of n-vias will be directly connected to the first metal plate 630-1, the vias which are directly connected are connected to each other not in serial but in parallel.

Because of the aforementioned reason, the parts except for the vias of the first multi-via and the second multi-via which will be directly connected to the metal plates (another vias and traces) are necessary to be electrically not connected to the metal plates directly. For the purpose of this, a clearance hole (refer to 730 of FIG. 7) can be formed in a certain part of the metal plates coinciding with a path of the parts except for the vias which will be directly connected to the metal plates.

Also, the same can be identically applied to the second multi-via.

In addition, FIG. 6 and FIG. 7 illustrate that a dielectric layer 620 is interposed between the metal plates 630-1, 630-2, 630-3 and 630-4 and the metal layer 610, and all vias constituting the first multi-via and the second multi-via penetrate through the dielectric layer 620 and expand to a same planar surface of the metal layer 610.

However, some vias constituting the first multi-via and the second multi-via can be formed in the direction above the metal plates or be manufactured as penetrating through the metal layer 610, unlike the drawing. Since a metal trace is manufactured as a certain pattern in any one planar surface, it is necessary that any two vias which will be connected to the metal trace are formed to expand to the pertinent planar surface in which the metal trace will be formed.

Moreover, FIG. 6 and FIG. 7 illustrate that all metal traces 721, 722, 723, 724 and 725 are manufactured as a straight-line form and the vias 711 through 716 are arrayed in a straight-line. However, it is possible that the metal traces can be manufactured as a line-form broken one or more times or a curved line-form besides a straight-line form, and the vias are not arrayed in a straight-line but some vias can be transformationally positioned out of the straight-line or the broken position.

In addition, FIG. 6 and FIG. 7 illustrate that a conductive connection pattern (refer to the metal trace of the reference numeral 725 of FIG. 7) electrically connecting the first multi-via and the second multi-via with each other is connecting the fifth via 715 and the sixth via 716 with each other. However, it is sufficient as long as the conductive connection pattern connecting the first multi-via and the second multi-via with each other only connects any one of vias 711, 713 and 715 constituting the first multi-via and any one of vias 712, 714 and 716 constituting the second multi-via.

In addition, although FIG. 6 and FIG. 7 illustrate that the metal layer 620 is placed below the metal plates, it can be omitted as described above with reference to FIG. 4. Only if the metal layer exists and constitutes a layer which is electrically different from the metal plates, since the metal layer 610 should not be electrically connected to the metal plates, a clearance hole can be formed in a part of the metal layer 610 coinciding with a path through which the multi-via connection part will pass, as described above.

The electromagnetic bandgap structure of the present invention can acquire more inductance component formed between any two metal plates than the structure of FIG. 4A and FIG. 4C, by electrical connection of the two metal plates through the multi-via connection part as described above.

Comparing the multi-via connection part shown in FIG. 6 and FIG. 7 with the stitching via of FIG. 4A and FIG. 4C, the fifth via 715, the sixth via 716 and the conductive connection pattern 725 of the multi-via connection part can correspond to the stitching via of FIG. 4A and FIG. 4C. Accordingly, a greater inductance component based on the first via 711 of the first multi-via->the first metal trace 721->the third via 713->the third metal trace 723 and a greater inductance component based on the second via 712 of the second multi-via->the second metal trace 722->the fourth via 714->the fourth metal trace 724 are acquired than by the structure of FIG. 4A and FIG. 4C.

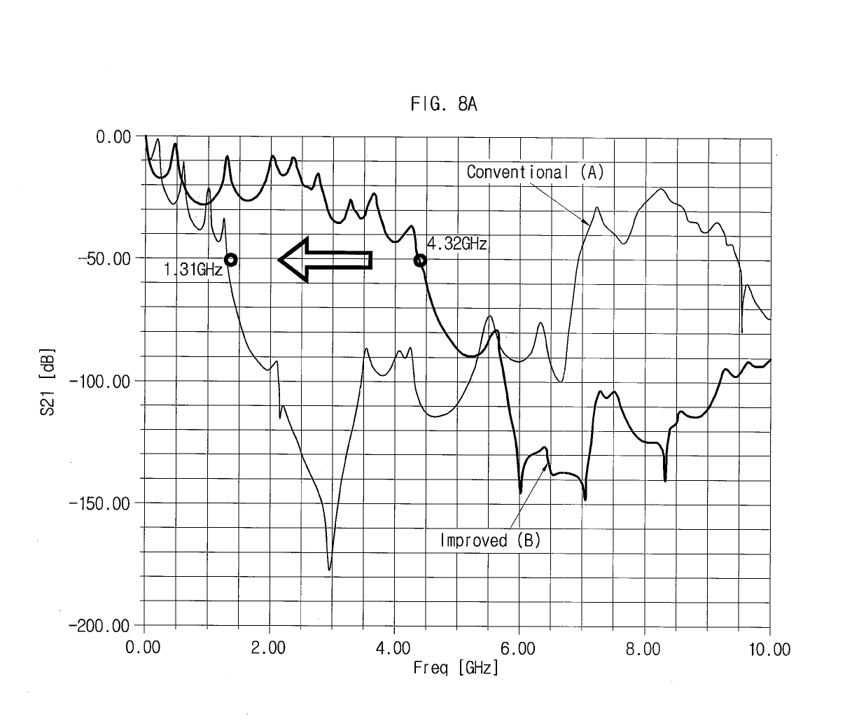

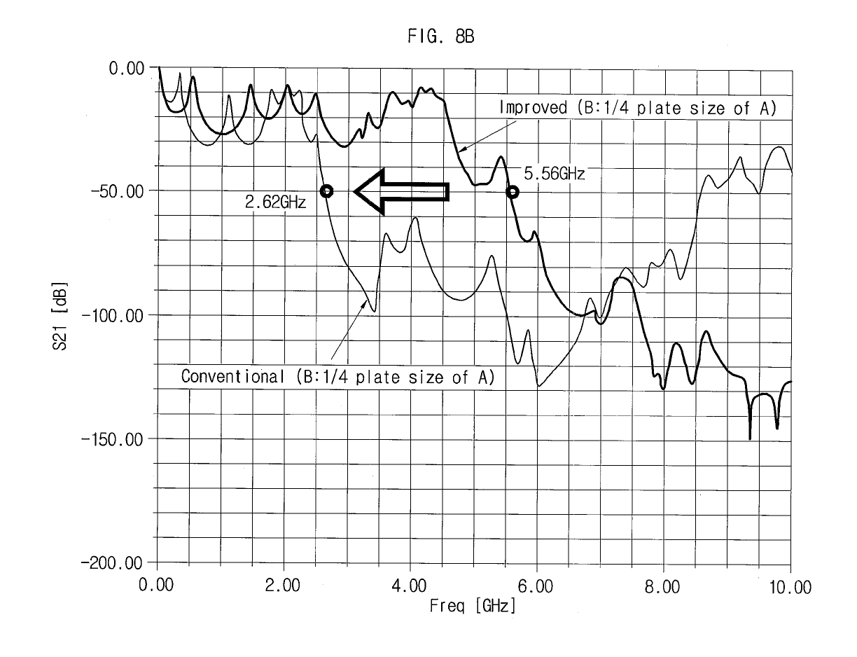

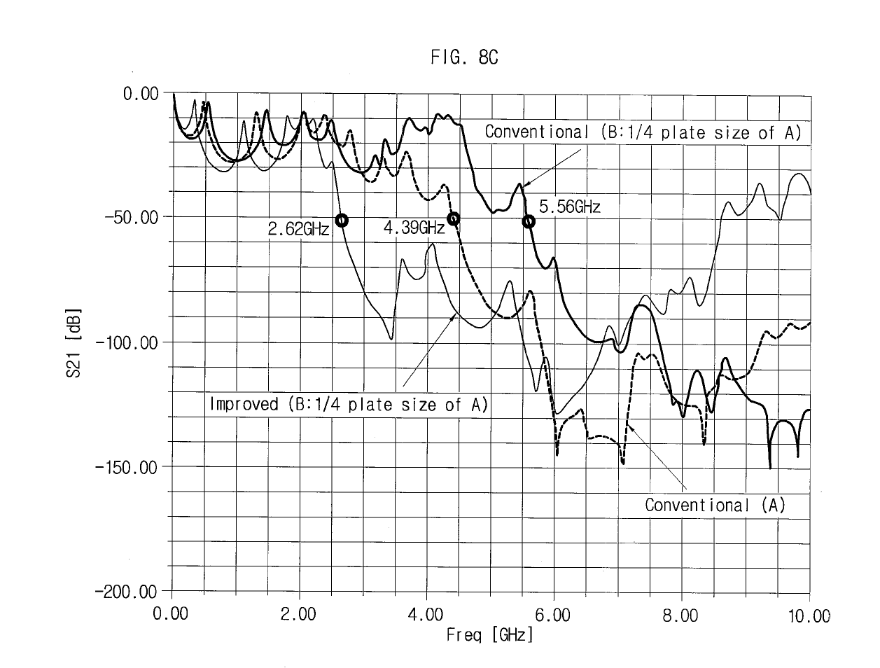

Accordingly, despite the same size of the metal plate, the electromagnetic bandgap structure including the multi-via connection part in accordance with the present invention is expected to have a lower bandgap frequency band than the structure of FIG. 4A and FIG. 4C. This can be clearly verified through the simulation result of FIG. 8A through FIG. 8C.

FIG. 8A through FIG. 8C show simulation results analyzed by scattering parameters in order to check whether an electromagnetic bandgap structure having a multi-via connection part provided by the present invention has the band blocking property of a certain frequency band.

With reference to FIG. 8A, while the electromagnetic bandgap structure of FIG. 4A has the bandgap frequency band formed from about 4.32 GHz on a blocking rate of −50 dB basis, it can be recognized that the electromagnetic bandgap structure shown in FIG. 6 has the bandgap frequency band formed from about 1.31 GHz on the same blocking rate (i.e. −50 dB) basis and the same design condition (i.e. the same metal plate size, same via length, same dielectric material, etc.). In other words, it can be seen that the electromagnetic bandgap structure shown in FIG. 6 has the bandgap frequency band lowered by about 3 GHz as compared with the electromagnetic bandgap structure of FIG. 4A.

FIG. 8B shows a simulation result when each metal size is decreased to ¼ of FIG. 8A. With reference to FIG. 8B, while the electromagnetic bandgap structure of FIG. 4A has the bandgap frequency band formed from about 5.56 GHz on a blocking rate of −50 dB basis, it can be recognized that the electromagnetic bandgap structure shown in FIG. 6 has the bandgap frequency band formed from about 2.62 GHz on the same blocking rate (i.e. −50 dB) basis and the same design condition. In other words, it can be seen that the electromagnetic bandgap structure shown in FIG. 6 has the bandgap frequency band lowered by about 3 GHz as compared with the electromagnetic bandgap structure of FIG. 4A.

The above observations are illustrated in FIG. 8C. With reference to FIG. 8C, even though the metal size is decreased to ¼ of FIG. 4A in the electromagnetic bandgap structure shown in FIG. 6, it can be seen that its bandgap frequency is formed in a lower band. As described above, this is because the inductance component value acquired by the multi-via connection part is larger. Accordingly, the present invention has an advantageous structure for making a smaller cell size (i.e. the metal plate size) of the electromagnetic bandgap structure for implementing the same bandgap frequency.

Although some embodiments of the present invention have been described, anyone of ordinary skill in the art to which the invention pertains should be able to understand that a very large number of permutations are possible without departing the spirit and scope of the present invention and its equivalents, which shall only be defined by the claims appended below.

What is claimed is:

1. An electromagnetic bandgap structure comprising:
a plurality of conductive plates; and
a multi-via connection part electrically connecting any two of the plurality of conductive plates with each other,
wherein the multi-via connection part comprises:
a first multi-via, including a first via, having one end part connected to one of the two conductive plates, and at least one other via connected in serial to the first via through a conductive trace;
a second multi-via, including a second via, having one end part connected to the other of the two conductive plates, and at least one other via connected in serial to the second via through a conductive trace; and
a conductive connection pattern, connecting any one of the vias included in the first multi-via and any one of the vias included in the second multi-via with each other.

2. The electromagnetic bandgap structure of claim 1, wherein the plurality of conductive plates are placed on a same planar surface.

3. The electromagnetic bandgap structure of claim 1, wherein a dielectric layer is placed above or below the plurality of conductive plates, and the vias included in the first multi-via and the second multi-via are formed to penetrate through the dielectric layer.

4. The electromagnetic bandgap structure of claim 3, wherein, if further comprising a conductive layer between the plurality of conductive plates and the dielectric layer, a clearance hole is formed in a part of the conductive layer coinciding with a path through which the multi-via connection part will pass such that the multi-via connection part and the conductive layer are electrically separated from each other.

5. The electromagnetic bandgap structure of claim 1, wherein a clearance hole is formed in a part coinciding with a path through which the multi-via connection part passes, except for parts of the conductive plates to be connected to the one end part of the first via and the one end part of the second via.

6. The electromagnetic bandgap structure of claim 1, wherein the conductive trace and the conductive connection pattern are manufactured as a straight-line form or a line form broken one or more times.

7. A printed circuit board comprising an electromagnetic bandgap structure, the electromagnetic bandgap structure including a plurality of conductive plates and a multi-via connection part electrically connecting any two of the plurality of conductive plates and disposed at an area of a noise transferable path between a noise source point and a noise blocking destination point of the printed circuit board,
wherein the multi-via connection part comprises:
a first multi-via, including a first via, having one end part connected to one of the two conductive plates, and at least one other via connected in serial to the first via through a conductive trace;
a second multi-via, including a second via, having one end part connected to the other of the two conductive plates, and at least one other via connected in serial to the second via through a conductive trace; and
a conductive connection pattern, connecting any one of the vias included in the first multi-via and any one of the vias included in the second multi-via with each other.

8. The printed circuit board of claim 7, wherein the plurality of conductive plates are placed on a same planar surface.

9. The printed circuit board of claim 7, wherein a dielectric layer is placed above or below the plurality of conductive plates, and the vias included in the first multi-via and the second multi-via are formed to penetrate through the dielectric layer.

10. The printed circuit board of claim 9, wherein, if further comprising a conductive layer between the plurality of conductive plates and the dielectric layer, a clearance hole is formed in a part of the conductive layer coinciding with a path through which the multi-via connection part will pass such that the multi-via connection part and the conductive layer are electrically separated from each other.

11. The printed circuit board of claim 10, wherein the conductive plates are electrically connected to one of a ground layer and a power layer, and the conductive layer is electrically connected to the other of the ground layer and the power layer.

12. The printed circuit board of claim 10, wherein the conductive plates are electrically connected to one of a ground layer and a signal layer, and the conductive layer is electrically connected to the other of the ground layer and the signal layer.

13. The printed circuit board of claim 7, wherein a clearance hole is formed in a part coinciding with a path through which the multi-via connection part passes, except for parts of the conductive plates to be connected to the one end part of the first via and the one end part of the second via.

14. The printed circuit board of claim 7, wherein the conductive trace and the conductive connection pattern can be manufactured as a straight-line form or a line form broken one or more times.

15. The printed circuit board of claim 7, wherein, if two electronic circuits having different operation frequencies are installed in the printed circuit board, the noise source point and the noise blocking destination point correspond to one position and another position, respectively, in which the two electric circuits are to be installed.
